(19) United States
(12) Patent Application Publication
(10) Pub. No.: US 2026/0309804 A1
(43) Pub. Date: Oct. 8, 2026

(54) Fault Detection Apparatus and Method

(71) Applicant: Reed Semiconductor Corporation

(72) Inventors: Biranchinath Sahu, Bangalore (IN); Ashwani Kumar Singh, Bengaluru (IN)

(21) Appl. No.: 19/171,141

(22) Filed: Apr. 4, 2025

(51) Int. Cl. G01R 31/54; H02M 1/00; H02M 1/088

(52) U.S. Cl. CPC G01R 31/54; H02M 1/0003; H02M 1/088

(57) ABSTRACT

An apparatus includes a current source coupled to a bias voltage bus, a plurality of positive voltage detection control switches coupled to a first terminal connected to a positive voltage sense line of a power conversion system, a plurality of negative voltage detection control switches coupled to a second terminal connected to a negative voltage sense line of the power conversion system, and a fault detection comparator comprising a non-inverting input coupled to the first terminal through one of the plurality of positive voltage detection control switches, and coupled to the second terminal through one of the plurality of negative voltage detection control switches, an inverting input configured to receive a predetermined fault detection threshold voltage, and an output configured to generate a fault detection signal indicating whether a sense line disconnection fault occurs.

### TECHNICAL FIELD

The present disclosure relates generally to the field of power conversion systems, and in particular embodiments, to a fault detection apparatus in a power conversion system.

### BACKGROUND

As technologies further advance, a variety of processors such as Digital Signal Processors (DSPs), Field Programmable Gate Arrays (FPGAs), Central Processing Units (CPUs) and/or the like, have become popular. Each processor operates with a low supply voltage (e.g., sub-1V) and consumes a large amount of current. A multiphase power conversion system is employed to power the processor. The multiphase power conversion system comprises a multiphase controller and a plurality of power stages.

The multiphase controller is an integrated circuit designed to manage and regulate power delivery in systems requiring high efficiency and stability. This type of controller is commonly used in power supplies for processors consuming a large amount of current. The multiphase controller is configured to control plurality of power stages by generating multiple Pulse Width Modulation (PWM) signals and monitoring current sense signals. The primary objective is to distribute the load across several phases, enhancing power delivery efficiency, reducing ripple, and improving overall performance.

The core of the multiphase controller is a PWM controller. In operation, the PWM controller generates precise PWM signals for each power stage. These signals are used to control the switching of power devices in each phase, regulating the voltage and current supplied to the load. The PWM signals are typically phase-shifted to interleave the switching of each power stage. This reduces the input and output ripple currents, thereby improving the overall efficiency and reducing the size of filtering components.

In operation, reliable operation of the multiphase power conversion system depends on accurate feedback from voltage sense lines, such as a positive voltage sense line VSNSP and a negative voltage sense line VSNSN, which are connected to the load to monitor output voltage. If these voltage sense lines become disconnected, the voltage feedback signal does not return to the multiphase controller, causing it to continue generating PWM signals. This uncontrolled switching action can result in an overvoltage condition, potentially damaging the load. Conventional fault detection methods often rely on redundant sensors or complex algorithms, which can increase system cost and design complexity. Therefore, there is a need for an improved approach to accurately detecting sense line disconnection faults in the multiphase power conversion system, enabling enhanced reliability and operational efficiency. The present disclosure addresses this need.

### SUMMARY

Technical advantages are generally achieved, by embodiments of this disclosure which describe a fault detection apparatus in a power conversion system.

In accordance with one aspect of the present disclosure, an apparatus comprises a current source coupled to a bias voltage bus, a plurality of positive voltage detection control switches coupled to a first terminal connected to a positive voltage sense line of a power conversion system, a plurality of negative voltage detection control switches coupled to a second terminal connected to a negative voltage sense line of the power conversion system, and a fault detection comparator comprising a non-inverting input coupled to the first terminal through one of the plurality of positive voltage detection control switches, and coupled to the second terminal through one of the plurality of negative voltage detection control switches, an inverting input configured to receive a predetermined fault detection threshold voltage, and an output configured to generate a fault detection signal indicating whether a sense line disconnection fault occurs.

In accordance with another aspect of the present disclosure, a method comprises enabling a current source to charge a terminal connected to a voltage sense line of a power conversion system, after a predetermined period, sampling a voltage at the terminal, comparing the voltage at the terminal with a predetermined threshold voltage, and reporting a sense line disconnection fault upon finding that the voltage on the terminal is greater than the predetermined threshold voltage.

In accordance with another aspect of the present disclosure, a power conversion system comprises a plurality of power converters connected in parallel connected between an input voltage bus and an output voltage bus, and a controller comprising a current source coupled to a bias voltage bus, a plurality of positive voltage detection control switches coupled to a first terminal connected to a positive voltage sense line of a power conversion system, a plurality of negative voltage detection control switches coupled to a second terminal connected to a negative voltage sense line of the power conversion system, and a fault detection comparator comprising a non-inverting input coupled to the first terminal through one of the plurality of positive voltage detection control switches, and coupled to the second terminal through one of the plurality of negative voltage detection control switches, an inverting input configured to receive a predetermined fault detection threshold voltage, and an output configured to generate a fault detection signal indicating whether a sense line disconnection fault occurs.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a power conversion system in accordance with various embodiments of the present disclosure;

FIG. 2 illustrates a schematic diagram of the smart power stage shown in FIG. 1 in accordance with various embodiments of the present disclosure;

FIG. 3 illustrates a block diagram of a fault detection apparatus in accordance with various embodiments of the present disclosure;

FIG. 4 illustrates a schematic diagram of the fault detection apparatus in accordance with various embodiments of the present disclosure;

FIG. 5 is a flow diagram of detecting the positive sense line disconnection fault in accordance with various embodiments of the present disclosure;

FIG. 6 is a flow diagram of detecting the negative sense line disconnection fault in accordance with various embodiments of the present disclosure; and

FIG. 7 illustrates a flow chart of a method for detecting a fault in the power conversion system shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to embodiments in a specific context, namely a fault detection apparatus in a multiphase power conversion system. The disclosure may also be applied, however, to a variety of power conversions systems. Hereinafter, various embodiments will be explained in detail with reference to the accompanying drawings.

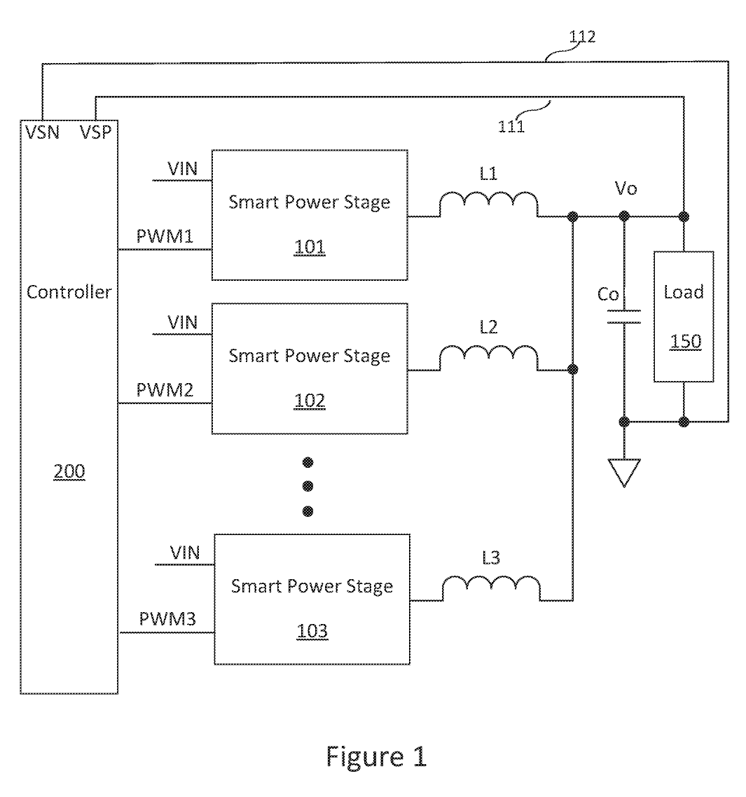

FIG. 1 illustrates a block diagram of a power conversion system in accordance with various embodiments of the present disclosure. The power conversion system comprises a controller 200, a first smart power stage 101, a first inductor L1, a second smart power stage 102, a second inductor L2, a third smart power stage 103, a third inductor L3, and an output capacitor Co.

As shown in FIG. 1, the first smart power stage 101 and the first inductor L1 are connected in series to form a first power conversion stage. In some embodiments, the first power conversion stage is a step-down power conversion stage. As shown in FIG. 1, this step-down power conversion stage is connected between an input voltage bus VIN and an output voltage bus Vo. Likewise, the second smart power stage 102 and the second inductor L2 are connected in series to form a second power conversion stage. In some embodiments, the second power conversion stage is a step-down power conversion stage. As shown in FIG. 1, this step-down power conversion stage is connected between the input voltage bus VIN and the output voltage bus Vo. The third smart power stage 103 and the third inductor L3 are connected in series to form a third power conversion stage. In some embodiments, the third power conversion stage is a step-down power conversion stage. As shown in FIG. 1, this step-down power conversion stage is connected between the input voltage bus VIN and the output voltage bus Vo.

It should be noted that FIG. 1 illustrates only three power conversion stages of a power conversion system that may include hundreds of such power conversion stages. The number of power conversion stages illustrated herein is limited solely for the purpose of clearly illustrating the inventive aspects of the various embodiments. The present invention is not limited to any specific number of power conversion stages.

An output capacitor Co is connected between the output voltage bus Vo and ground. In some embodiments, the output capacitor Co is approximately 1 microfarad. A load 150 is coupled to the output voltage bus Vo. In some embodiments, the load may be a processor (e.g., a central processing unit).

The controller 200 is a multiphase controller. As shown in FIG. 1, the controller 200 is connected to the plurality of smart power stages 101, 102 and 103. The controller 200 feeds a PWM signal PWM1 to the first smart power stage 101. The controller 200 feeds a PWM signal PWM2 to the second smart power stage 102. The controller 200 feeds a PWM signal PWM3 to the third smart power stage 103. In operation, the controller 200 is configured to detect the output voltage of the power conversion system through a positive voltage sense line 111 and a negative voltage sense line 112. As shown in FIG. 1, the positive voltage sense line 111 is connected between a VSP terminal of the controller 200 and a positive terminal of the load 150. Throughout the description, the VSP terminal is alternatively referred to as a first terminal. The negative voltage sense line 112 is connected between a VSN terminal of the controller 200 and a negative terminal of the load 150. Throughout the description, the VSN terminal is alternatively referred to as a second terminal. The voltage sense lines 111 and 112 are employed to measure the actual voltage across the load 150. In operation, the voltage sense lines 111 and 112 carry negligible current to avoid introducing additional voltage drop errors. This configuration of the voltage sense lines 111 and 112 ensures that the regulated voltage is accurate at the load rather than just at the terminals of the power conversion system.

In some embodiments, the controller 200 may be a system controller or a system control apparatus. The controller 200 may be implemented as a microprocessor, a digital signal processor and the like.

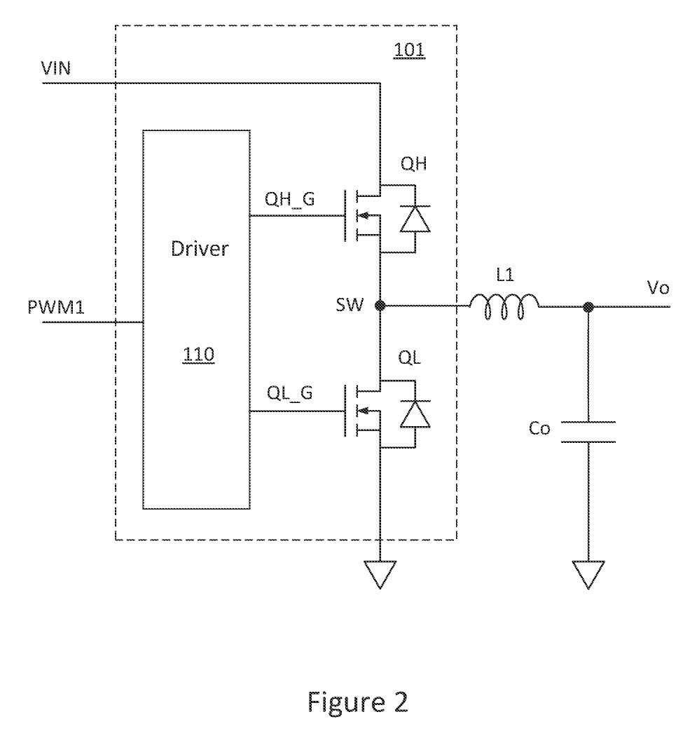

In some embodiments, the power conversion stage formed by the smart power stage 101, the inductor L1 and the output capacitor Co is implemented as a step-down power converter. In some embodiments, the smart power stage 101 comprises both high side and low side power switches responsible for regulating the output voltage of the step-down power converter. The smart power stage 101 also includes the gate driver circuitry that controls the high side and low side power switches, optimizing the switching operation for speed and efficiency. The smart power stage 101 may further comprise other key components such as current sensing, temperature sensing, overcurrent protection, overvoltage protection, under-voltage protection and various digital communication interfaces. The detailed structure of the smart power stage 101 will be described below with respect to FIG. 2.

Alternatively, the power conversion stage may be implemented as any suitable power converters such as an inductor-inductor-capacitor (LLC) converter, a switched capacitor converter, a hybrid switched capacitor converter, a full bridge power converter, a half bridge power converter, a buck converter, any combinations thereof and the like.

In some embodiments, the controller 200 is constant on-time controller. A constant on-time control scheme is employed to control the power conversions system. The control loop of the constant on-time control scheme includes a feedback comparator and an on-timer. In operation, a feedback signal of the output voltage is directly compared with a predetermined reference. When the feedback signal falls below the predetermined reference, the high side switch is turned on and remains on for the on-timer duration. The high side switch turns off when the on-timer expires, and does not turn on until the feedback signal falls below the internal reference again.

FIG. 2 illustrates a schematic diagram of the smart power stage shown in FIG. 1 in accordance with various embodiments of the present disclosure. The smart power stage 101 comprises a high side switch QH, a low side switch QL and a driver 110. As shown in FIG. 2, the high side switch QH and the low side switch QL are connected in series between the input voltage bus VIN and ground. An output inductor L1 is connected between a common node (SW) of the high side switch QH and the low side switch QL, and the output voltage bus Vo. The output capacitor Co is connected between the output voltage bus Vo and ground. The driver 110 is configured to receive a PWM signal (PWM1) from the controller 200. Based on the received PWM signal, the driver 110 generates gate drive signals QH_G and QL_G for the high side switch QH and the low side switch QL, respectively. In some embodiments, the high side switch QH, the low side switch QL and the driver 110 are in a smart power stage semiconductor package.

In operation, when the high side switch QH is turned on, and the low side switch QL is turned off, a current flows from the input voltage VIN to the load through the output inductor L1. The output inductor L1 opposes sudden changes in current by storing energy in its magnetic field. The output capacitor Co supplies the load with current, smoothing out the output voltage Vo. When the high side switch QH is turned off, and the low side switch QL is turned on, the output inductor L1 releases its stored energy to maintain the current flow to the load. The output capacitor Co continues to smooth the output voltage. In operation, the duty cycle (the ratio of the turn-on time of the high side switch QH to the total switching period) is used to control the output voltage Vo. By adjusting the duty cycle, the output voltage Vo can be regulated at a predetermined level.

In accordance with an embodiment, the switches (e.g., switches QH and QL) may be metal oxide semiconductor field-effect transistor (MOSFET) devices. Alternatively, the switches can be any controllable switches such as insulated gate bipolar transistor (IGBT) devices, integrated gate commutated thyristor (IGCT) devices, gate turn-off thyristor (GTO) devices, silicon-controlled rectifier (SCR) devices, junction gate field-effect transistor (JFET) devices, MOS controlled thyristor (MCT) devices, gallium nitride (GaN)-based power devices, silicon carbide (SiC)-based power devices and the like.

It should be noted while FIG. 2 shows the switches QH and QL are implemented as single n-type transistors, a person skilled in the art would recognize there may be many variations, modifications and alternatives. For example, depending on different applications and design needs, the switches QH and QL may be implemented as p-type transistors. Furthermore, each switch shown in FIG. 2 may be implemented as a plurality of switches connected in parallel. Moreover, a capacitor may be connected in parallel with one switch to achieve zero voltage switching (ZVS)/zero current switching (ZCS).

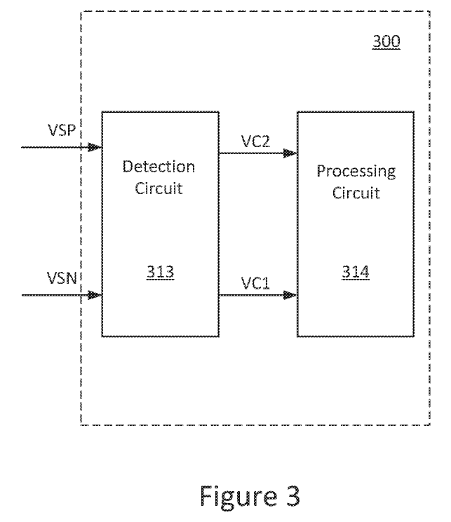

FIG. 3 illustrates a block diagram of a fault detection apparatus in accordance with various embodiments of the present disclosure. The controller 200 shown in FIG. 1 comprises a fault detection apparatus 300 configured to detect sense line disconnection faults in the power conversion system. More particularly, the fault detection apparatus 300 is configured to enable a current source to charge a terminal (e.g., VSP and/or VSN) connected to a voltage sense line of the power conversion system, after a predetermined period, sample a voltage at the terminal, compare the voltage at the terminal with a predetermined threshold voltage, and report a sense line disconnection fault upon finding that the voltage on the terminal is greater than predetermined threshold voltage.

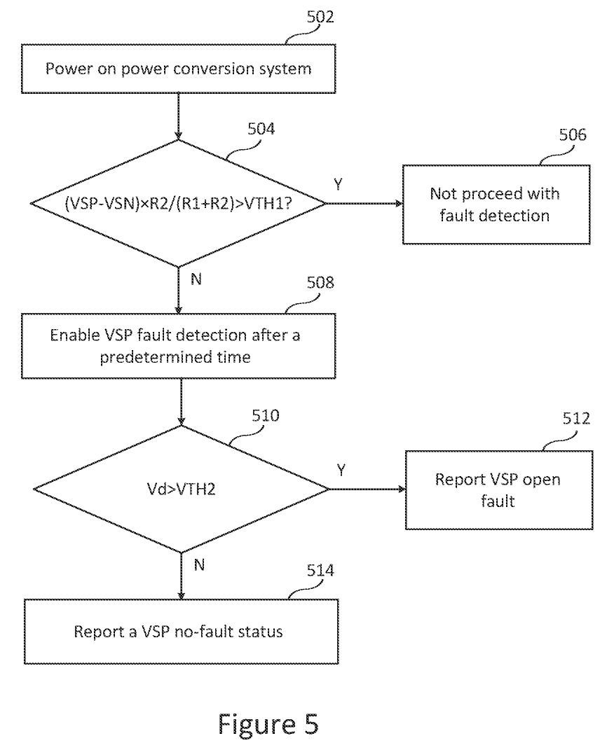

The fault detection apparatus 300 comprises a detection circuit 313 and a processing circuit 314. As shown in FIG. 3, the detection circuit 313 is configured to receive the voltages at the VSP and VSN terminals. Based on the received signals, the detection circuit 313 is configured to generate a fault detection signal VC2 indicating whether a sense line disconnection fault occurs and a pre-bias detection signal VC1 indicating whether a nonzero voltage exists across the positive voltage sense line and the negative voltage sense line of the power conversion system. Both VC1 and VC2 are fed into the processing circuit 314. Based on VC1 and VC2, the processing circuit 314 is able to determine whether a sense line disconnection fault exists prior to initiating a startup process of the power conversion system. The detailed operating principles of the detection circuit 313 and the processing circuit 314 will be discussed below with respect to FIGS. 5-7.

In some embodiments, the detection circuit 313 comprises the current source, a plurality of positive voltage detection control switches, a plurality of negative voltage detection control switches and a fault detection comparator. In some embodiments, a first positive voltage detection control switch is connected between the current source and the VSP terminal. A second positive voltage detection control switch is connected between the VSP terminal and the non-inverting input of the fault detection comparator. A first negative voltage detection control switch is connected between the current source and the VSN terminal. A second negative voltage detection control switch is connected between the VSN terminal and the non-inverting input of the fault detection comparator. In operation, the first positive voltage detection control switch and the second positive voltage detection control switch are controlled by a positive sense line disconnection fault detection signal. The first negative voltage detection control switch and the second negative voltage detection control switch are controlled by a negative sense line disconnection fault detection signal.

In the process of detecting a positive sense line disconnection fault, the first negative voltage detection control switch and the second negative voltage detection control switch are turned off. The first positive voltage detection control switch and the second positive voltage detection control switch are turned on to enable the current source to charge the first terminal (VSP). After a first predetermined period, a voltage at the first terminal is sampled. The sampled voltage at the first terminal is compared with a predetermined threshold voltage (e.g., 200 millivolts). The detection circuit 313 generates a signal VC2 indicating a positive sense line disconnection fault upon finding that the voltage on the first terminal is greater than predetermined threshold voltage.

In the process of detecting a negative sense line disconnection fault, the first positive voltage detection control switch and the second positive voltage detection control switch are turned off. The first negative voltage detection control switch and the second negative voltage detection control switch are turned on to enable the current source to charge the second terminal (VSN). After a second predetermined period, a voltage at the second terminal is sampled. The sampled voltage at the second terminal is compared with a predetermined threshold voltage (e.g., 200 millivolts). The detection circuit 313 generates a signal VC2 indicating a negative sense line disconnection fault upon finding that the voltage on the second terminal is greater than predetermined threshold voltage.

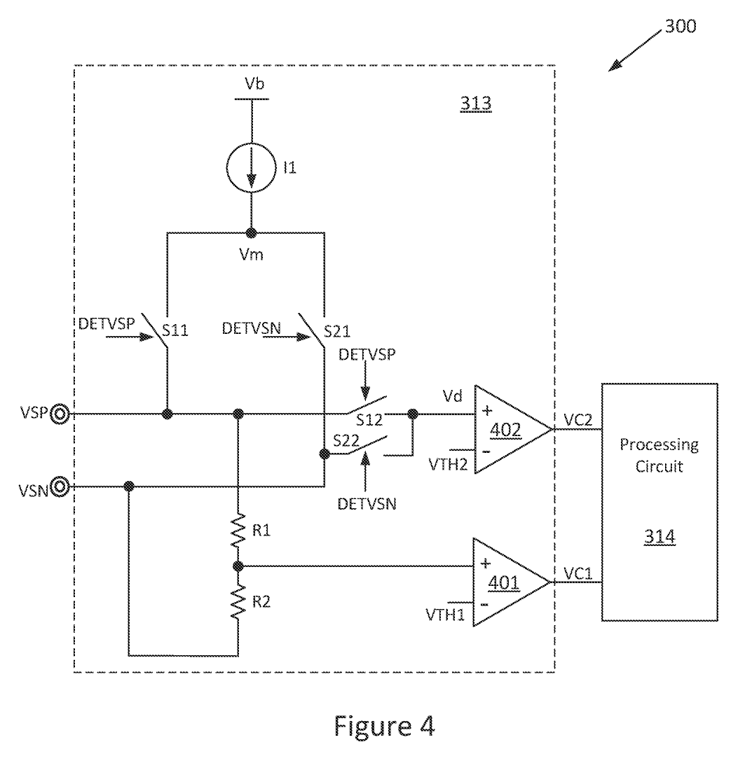

FIG. 4 illustrates a schematic diagram of the fault detection apparatus in accordance with various embodiments of the present disclosure. The fault detection apparatus 300 comprises a detection circuit 313 and a processing circuit 314. The detection circuit 313 comprises a current source I1, a first positive voltage detection control switch S11, a second positive voltage detection control switch S12, a first negative voltage detection control switch S21, the second negative voltage detection control switch S22, a resistor divider formed by resistors R1 and R2, a fault detection comparator 402 and a pre-bias detection comparator 401.

As shown in FIG. 4, the current source I1 is connected between a bias voltage bus Vb and an intermediate node Vm. The first positive voltage detection control switch S11 is connected between the intermediate node Vm and a first terminal (VSP). Referring back to FIG. 1, VSP is connected to the positive voltage sense line 111 of the power conversion system. The first negative voltage detection control switch S21 is connected between the intermediate node Vm and a second terminal (VSN). Referring back to FIG. 1, VSN is connected to the negative voltage sense line 112 of the power conversion system. The second positive voltage detection control switch S12 is connected between the first terminal (VSP) and a non-inverting input of the fault detection comparator 402. The second negative voltage detection control switch S22 is connected between the second terminal (VSN) and the non-inverting input of the fault detection comparator 402. An inverting input of the fault detection comparator 402 is configured to receive a predetermined fault detection threshold voltage VTH2. In some embodiments, the predetermined fault detection threshold voltage VTH2 is equal to 200 millivolts.

The resistors R1 and R2 are connected in series between the first terminal (VSP) and the second terminal (VSN). A common node of R1 and R2 is also referred to as a midpoint of the resistor divider. As shown in FIG. 4, the midpoint of the resistor divider is connected to a non-inverting input of the pre-bias detection comparator 401. An inverting input of the pre-bias detection comparator 401 is configured to receive a predetermined pre-bias detection threshold voltage VTH1. In some embodiments, the predetermined pre-bias detection threshold voltage VTH1 is equal to 50 millivolts.

In operation, after the power conversion system is powered on, various bias voltages (e.g., Vb) have been established. The pre-bias detection comparator 401 is configured to compare a scaled-down output voltage (the voltage at the midpoint of the resistor divider) with the predetermined pre-bias detection threshold voltage VTH1. If the scaled-down output voltage is greater than the predetermined pre-bias detection threshold voltage VTH1, the output of the pre-bias detection comparator 401 is configured to generate a pre-bias detection signal VC1 indicating that a nonzero voltage exists across the positive voltage sense line and the negative voltage sense line of the power conversion system. In response to this pre-bias detection signal VC1, the processing circuit 314 configures the fault detection apparatus not to proceed with the positive sense line disconnection fault detection.

In operation, if the pre-bias voltage does not exist across the positive voltage sense line and the negative voltage sense line of the power conversion system, the fault detection apparatus is configured to proceed with the positive sense line disconnection fault detection. The negative sense line disconnection fault detection occurs irrespective of the pre-bias status. In the process of detecting a positive sense line disconnection fault, the fault detection apparatus executes the following steps: turning on the first positive voltage detection control switch S11 and the second positive voltage detection control switch S12 to enable the current source I1 to charge the first terminal (VSP) of the controller 200, after a first predetermined period (e.g., 3 microseconds), sampling a voltage at the first terminal, comparing the voltage at the first terminal with a predetermined threshold voltage VTH2, and reporting a positive sense line disconnection fault upon finding that the voltage on the first terminal is greater than predetermined threshold voltage VTH2. In the process of detecting a negative sense line disconnection fault, the fault detection apparatus executes the following steps: turning on the first negative voltage detection control switch S21 and the second negative voltage detection control switch S22 to enable the current source I1 to charge the second terminal (VSN) of the controller 200, after a second predetermined period (e.g., 3 microseconds), sampling a voltage at the second terminal, comparing the voltage at the second terminal with a predetermined threshold voltage VTH2, and reporting a negative sense line disconnection fault upon finding that the voltage on the second terminal is greater than predetermined threshold voltage VTH2.

FIG. 5 is a flow diagram of detecting the positive sense line disconnection fault in accordance with various embodiments of the present disclosure. At step 502, the power conversion system is powered on. Various bias voltages have been established. At step 504, a scaled-down output voltage is compared with a predetermined pre-bias detection threshold voltage VTH1. If the scaled-down output voltage is greater than the predetermined pre-bias detection threshold voltage VTH1 (YES at step 504), a pre-bias operating condition is reported, and the fault detection apparatus does not proceed with the sense line disconnection fault detection at step 506. If the scaled-down output voltage is less than the predetermined pre-bias detection threshold voltage VTH1 (NO at step 504), the fault detection apparatus is configured to proceed with the positive sense line disconnection fault detection. At step 508, the current source is configured to charge the first terminal (VSP). After a first predetermined period, the voltage at the first terminal is sampled. At step 510, the sampled voltage at the first terminal is compared with a predetermined threshold voltage VTH2. If the sampled voltage at the first terminal is greater than the predetermined threshold voltage VTH2 (YES at step 510), a positive sense line disconnection fault is reported at step 512. If the sampled voltage at the first terminal is less than the predetermined threshold voltage VTH2 (No at step 510), a positive sense line no-fault status is reported at step 514.

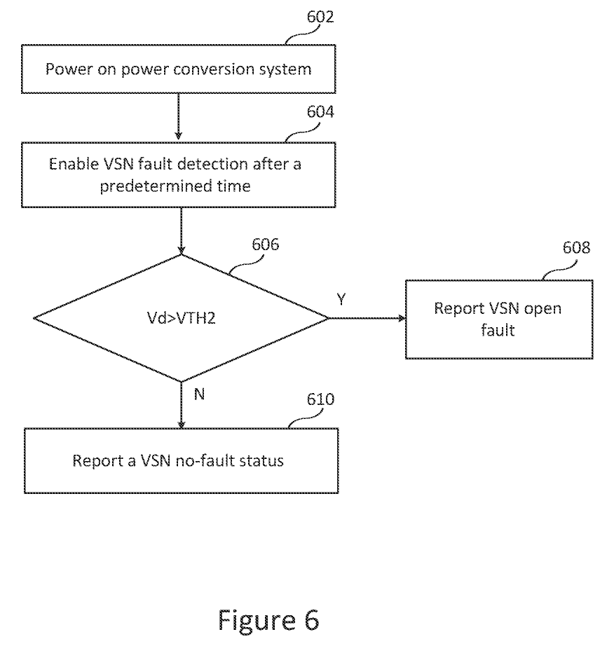

FIG. 6 is a flow diagram of detecting the negative sense line disconnection fault in accordance with various embodiments of the present disclosure. At step 602, the power conversion system is powered on. Various bias voltages have been established. At step 604, the fault detection apparatus is configured to proceed with the negative sense line disconnection fault detection. The current source is configured to charge the second terminal (VSN). After a second predetermined period, the voltage at the second terminal is sampled. At step 606, the sampled voltage at the second terminal is compared with a predetermined threshold voltage VTH2. If the sampled voltage at the second terminal is greater than the predetermined threshold voltage VTH2 (YES at step 606), a negative sense line disconnection fault is reported at step 608. If the sampled voltage at the second terminal is less than the predetermined threshold voltage VTH2 (No at step 606), a negative sense line no-fault status is reported at step 610.

It should be noted that, depending on design requirements and application needs, the fault detection processes illustrated in FIGS. 5 and 6 may be performed independently or sequentially. When executed sequentially, the detection of a positive sense line disconnection fault may occur before the detection of a negative sense line disconnection fault, or vice versa.

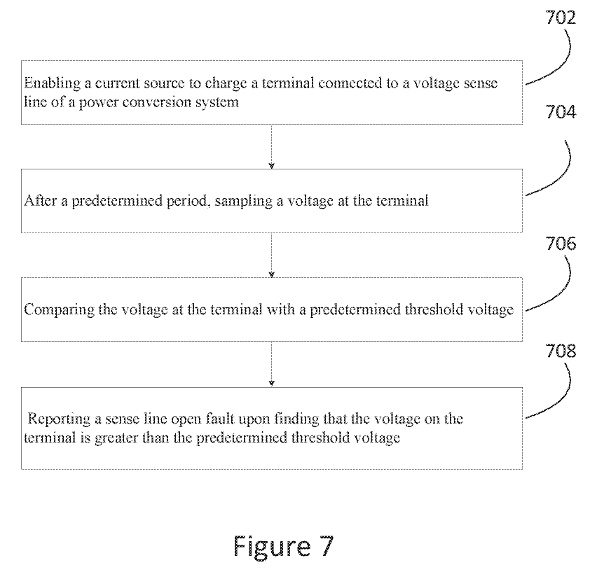

FIG. 7 illustrates a flow chart of a method for detecting a fault in the power conversion system shown in FIG. 1 in accordance with various embodiments of the present disclosure. This flowchart shown in FIG. 7 is merely an example, which should not unduly limit the scope of the claims. One of ordinary skill in the art would recognize many variations, alternatives, and modifications. For example, various steps illustrated in FIG. 7 may be added, removed, replaced, rearranged and repeated.

At step 702, a current source is enabled to charge a terminal connected to a voltage sense line of a power conversion system.

At step 704, after a predetermined period, a voltage at the terminal is sampled.

At step 706, the voltage at the terminal is compared with a predetermined threshold voltage.

At step 708, a sense line disconnection fault is reported upon finding that the voltage on the terminal is greater than the predetermined threshold voltage.

In some embodiments, the current source, a plurality of positive voltage detection control switches, a plurality of negative voltage detection control switches, a fault detection comparator and a processing circuit form a sense line disconnection fault detection apparatus.

In some embodiments, a first positive voltage detection control switch is connected between the current source and a first terminal connected to a positive voltage sense line of the power conversion system, a second positive voltage detection control switch is connected between the first terminal and the non-inverting input of the fault detection comparator, a first negative voltage detection control switch is connected between the current source and a second terminal connected to a negative voltage sense line of the power conversion system, and a second negative voltage detection control switch is connected between the second terminal and the non-inverting input of the fault detection comparator, and wherein the first positive voltage detection control switch and the second positive voltage detection control switch are controlled by a positive sense line disconnection fault detection signal, and the first negative voltage detection control switch and the second negative voltage detection control switch are controlled by a negative sense line disconnection fault detection signal.

The method further comprises turning on the first positive voltage detection control switch and the second positive voltage detection control switch to enable the current source to charge the first terminal connected to the positive voltage sense line of the power conversion system, after a first predetermined period, sampling a voltage at the first terminal, comparing the voltage at the first terminal with a predetermined threshold voltage, and reporting a positive sense line disconnection fault upon finding that the voltage on the first terminal is greater than predetermined threshold voltage.

The method further comprises turning on the first negative voltage detection control switch and the second negative voltage detection control switch to enable the current source to charge the second terminal connected to the negative voltage sense line of the power conversion system, after a second predetermined period, sampling a voltage at the second terminal, comparing the voltage at the second terminal with a predetermined threshold voltage, and reporting a negative sense line disconnection fault upon finding that the voltage on the second terminal is greater than predetermined threshold voltage.

In some embodiments, the sense line disconnection fault detection apparatus further comprises a resistor divider connected between the first terminal and the second terminal, and a pre-bias detection comparator comprising a non-inverting input connected to a midpoint of the resistor divider, an inverting input configured to receive a predetermined pre-bias detection threshold voltage, and an output configured to generate a pre-bias detection signal indicating whether a nonzero voltage exists across the positive voltage sense line and the negative voltage sense line of the power conversion system.

In some embodiments, the step of determining whether the nonzero voltage exists across the positive voltage sense line and the negative voltage sense line of the power conversion system is carried out before the step of determining whether a sense line disconnection fault occurs in the power conversion system.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. An apparatus comprising:
a current source coupled to a bias voltage bus;
a plurality of positive voltage detection control switches coupled to a first terminal connected to a positive voltage sense line of a power conversion system;
a plurality of negative voltage detection control switches coupled to a second terminal connected to a negative voltage sense line of the power conversion system; and
a fault detection comparator comprising:
a non-inverting input coupled to the first terminal through one of the plurality of positive voltage detection control switches, and coupled to the second terminal through one of the plurality of negative voltage detection control switches;
an inverting input configured to receive a predetermined fault detection threshold voltage; and
an output configured to generate a fault detection signal indicating whether a sense line disconnection fault occurs.

2. The apparatus of claim 1, further comprising:
a resistor divider connected between the first terminal and the second terminal; and
a pre-bias detection comparator comprising:
a non-inverting input connected to a midpoint of the resistor divider;
an inverting input configured to receive a predetermined pre-bias detection threshold voltage; and
an output configured to generate a pre-bias detection signal indicating whether a nonzero voltage exists across the positive voltage sense line and the negative voltage sense line of the power conversion system.

3. The apparatus of claim 2, further comprising:
a processing circuit configured to receive the fault detection signal and the pre-bias detection signal, wherein:
the processing circuit is configured to determine whether a sense line disconnection fault exists prior to initiating a startup process of the power conversion system.

4. The apparatus of claim 2, wherein:
a first positive voltage detection control switch of the plurality of positive voltage detection control switches is connected between the current source and the first terminal;
a second positive voltage detection control switch of the plurality of positive voltage detection control switches is connected between the first terminal and the non-inverting input of the fault detection comparator;
a first negative voltage detection control switch of the plurality of negative voltage detection control switches is connected between the current source and the second terminal; and
a second negative voltage detection control switch of the plurality of negative voltage detection control switches is connected between the second terminal and the non-inverting input of the fault detection comparator.

5. The apparatus of claim 4, wherein:
the first positive voltage detection control switch and the second positive voltage detection control switch are controlled by a positive sense line disconnection fault detection signal; and
the first negative voltage detection control switch and the second negative voltage detection control switch are controlled by a negative sense line disconnection fault detection signal.

6. The apparatus of claim 1, further comprising:
an output capacitor coupled between two output terminals of the power conversion system.

7. The apparatus of claim 6, wherein:
a current flowing through the current source is 200 microamperes;
the output capacitor is a 1uF capacitor; and
the predetermined fault detection threshold voltage is 200 millivolts.

8. The apparatus of claim 1, wherein:
the power conversion system comprises a plurality of power converters connected in parallel between an input voltage bus and a load, and wherein one of the plurality of power converters comprises a high side switch, a low side switch and an inductor, and wherein:
the high side switch and the low side switch are connected in series between the input voltage bus and ground; and
the inductor is connected between a common node of the high side switch and the low side switch, and an output voltage bus connected to the load.

9. The apparatus of claim 8, further comprising
a driver configured to receive a PWM signal, and generate a high side gate drive signal for the high side switch and a low side gate drive signal for the low side switch.

10. The apparatus of claim 9, wherein:
the high side switch, the low side switch and the driver form a smart power stage.

11. A method comprising:
enabling a current source to charge a terminal connected to a voltage sense line of a power conversion system;
after a predetermined period, sampling a voltage at the terminal;
comparing the voltage at the terminal with a predetermined threshold voltage; and
reporting a sense line disconnection fault upon finding that the voltage on the terminal is greater than the predetermined threshold voltage.

12. The method of claim 11, wherein:
the current source, a plurality of positive voltage detection control switches, a plurality of negative voltage detection control switches, a fault detection comparator and a processing circuit form a sense line disconnection fault detection apparatus.

13. The method of claim 12, wherein:
a first positive voltage detection control switch is connected between the current source and a first terminal connected to a positive voltage sense line of the power conversion system;
a second positive voltage detection control switch is connected between the first terminal and the non-inverting input of the fault detection comparator;
a first negative voltage detection control switch is connected between the current source and a second terminal connected to a negative voltage sense line of the power conversion system; and
a second negative voltage detection control switch is connected between the second terminal and the non-inverting input of the fault detection comparator, and wherein the first positive voltage detection control switch and the second positive voltage detection control switch are controlled by a positive sense line disconnection fault detection signal, and the first negative voltage detection control switch and the second negative voltage detection control switch are controlled by a negative sense line disconnection fault detection signal.

14. The method of claim 13, further comprising:
turning on the first positive voltage detection control switch and the second positive voltage detection control switch to enable the current source to charge the first terminal connected to the positive voltage sense line of the power conversion system;
after a first predetermined period, sampling a voltage at the first terminal;
comparing the voltage at the first terminal with a predetermined threshold voltage; and
reporting a positive sense line disconnection fault upon finding that the voltage on the first terminal is greater than predetermined threshold voltage.

15. The method of claim 13, further comprising:
turning on the first negative voltage detection control switch and the second negative voltage detection control switch to enable the current source to charge the second terminal connected to the negative voltage sense line of the power conversion system;
after a second predetermined period, sampling a voltage at the second terminal;
comparing the voltage at the second terminal with a predetermined threshold voltage; and
reporting a negative sense line disconnection fault upon finding that the voltage on the second terminal is greater than predetermined threshold voltage.

16. The method of claim 13, wherein the sense line disconnection fault detection apparatus further comprises:
a resistor divider connected between the first terminal and the second terminal; and
a pre-bias detection comparator comprising:
a non-inverting input connected to a midpoint of the resistor divider;
an inverting input configured to receive a predetermined pre-bias detection threshold voltage; and
an output configured to generate a pre-bias detection signal indicating whether a nonzero voltage exists across the positive voltage sense line and the negative voltage sense line of the power conversion system.

17. The method of claim 16, wherein:
the step of determining whether the nonzero voltage exists across the positive voltage sense line and the negative voltage sense line of the power conversion system is carried out before the step of determining whether a sense line disconnection fault occurs in the power conversion system.

18. A power conversion system comprising:
a plurality of power converters connected in parallel connected between an input voltage bus and an output voltage bus; and
a controller comprising:
a current source coupled to a bias voltage bus;
a plurality of positive voltage detection control switches coupled to a first terminal connected to a positive voltage sense line of a power conversion system;
a plurality of negative voltage detection control switches coupled to a second terminal connected to a negative voltage sense line of the power conversion system; and
a fault detection comparator comprising:
a non-inverting input coupled to the first terminal through one of the plurality of positive voltage detection control switches, and coupled to the second terminal through one of the plurality of negative voltage detection control switches;
an inverting input configured to receive a predetermined fault detection threshold voltage; and
an output configured to generate a fault detection signal indicating whether a sense line disconnection fault occurs.

19. The power conversion system of claim 18, wherein one of the plurality of power converters comprises a high side switch, a low side switch and an inductor, and wherein:
the high side switch and the low side switch are connected in series between the input voltage bus and ground; and
the inductor is connected between a common node of the high side switch and the low side switch, and the output voltage bus.

20. The power conversion system of claim 19, further comprising:
a resistor divider connected between the first terminal and the second terminal;
a pre-bias detection comparator comprising:
a non-inverting input connected to a midpoint of the resistor divider;
an inverting input configured to receive a predetermined pre-bias detection threshold voltage; and
an output configured to generate a pre-bias detection signal indicating whether a nonzero voltage exists across the positive voltage sense line and the negative voltage sense line of the power conversion system; and
a processing circuit configured to receive the fault detection signal and the pre-bias detection signal, wherein the processing circuit is configured to determine whether a sense line disconnection fault exists prior to initiating a startup process of the power conversion system, wherein:
a first positive voltage detection control switch is connected between the current source and the first terminal;
a second positive voltage detection control switch is connected between the first terminal and the non-inverting input of the fault detection comparator;
a first negative voltage detection control switch is connected between the current source and the second terminal; and
a second negative voltage detection control switch is connected between the second terminal and the non-inverting input of the fault detection comparator, and wherein:
the first positive voltage detection control switch and the second positive voltage detection control switch are controlled by a positive sense line disconnection fault detection signal; and
the first negative voltage detection control switch and the second negative voltage detection control switch are controlled by a negative sense line disconnection fault detection signal.
